(19) United States
(12) Patent Application Publication
(10) Pub. No.: US 2026/0101685 A1
(43) Pub. Date: Apr. 9, 2026

(54) CYCLIC ETCH OF SILICON OXIDE AND POLYSILICON

(71) Applicant: Applied Materials, Inc., Santa Clara, CA (US)

(72) Inventors: Mang-Mang Ling, San Jose, CA (US); Jong Mun Kim, San Jose, CA (US); Hailong Zhou, San Jose, CA (US); Srinivas D. Nemani, Saratoga, CA (US); Ellie Y. Yieh, San Jose, CA (US); Lei Zhang, Santa Clara, CA (US)

(73) Assignee: Applied Materials, Inc., Santa Clara, CA (US)

(21) Appl. No.: 19/200,076

(22) Filed: May 6, 2025

Related U.S. Application Data
(60) Provisional application No. 63/703,666, filed on Oct. 4, 2024.
(60) Provisional application No. 63/762,542, filed on Feb. 24, 2025.

(51) Int. Cl. H01L 21/02

(52) U.S. Cl. CPC H10P 14/6532; H10P 14/69215

(57) ABSTRACT

Exemplary semiconductor processing methods may include providing one or more first etchant precursors to a processing region of a semiconductor processing chamber. A substrate may be housed within the processing region. A plurality of pairs of silicon oxide material and polysilicon material may be disposed on the substrate. The methods may include forming plasma effluents of the one or more first etchant precursors and contacting the substrate with the plasma effluents of the one or more first etchant precursors to selectively etch silicon oxide material. The methods may include providing one or more second etchant precursors to the processing region, forming plasma effluents of the one or more second etchant precursors, and contacting the substrate with the plasma effluents of the one or more second etchant precursors to selectively etch polysilicon material. A temperature within the processing region may be greater than or about 0° C.

### CROSS-REFERENCE TO RELATED APPLICATIONS

This application claims the benefit of, and priority to U.S. Provisional Application Ser. No. 63/703,666, filed Oct. 4, 2024, and U.S. Provisional Application Ser. No. 63/762,542, filed Feb. 24, 2025, which are hereby incorporated by reference in their entirety for all purposes.

### TECHNICAL FIELD

The present technology relates to semiconductor processes and equipment. More specifically, the present technology relates to cyclically etching silicon oxide material and polysilicon material.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing one or more first etchant precursors to a processing region of a semiconductor processing chamber. A substrate may be housed within the processing region. A plurality of pairs of silicon oxide material and polysilicon material may be disposed on the substrate. The methods may include forming plasma effluents of the one or more first etchant precursors. The methods may include contacting the substrate with the plasma effluents of the one or more first etchant precursors to selectively etch silicon oxide material. The methods may include providing one or more second etchant precursors to the processing region of the semiconductor processing chamber. The methods may include forming plasma effluents of the one or more second etchant precursors. The methods may include contacting the substrate with the plasma effluents of the one or more second etchant precursors to selectively etch polysilicon material. A temperature within the processing region may be greater than or about 0° C.

In embodiments, a patterned mask material may be disposed on the alternating stack of silicon oxide material and polysilicon material. The patterned mask material may be or include a carbon-containing material. The one or more first etchant precursors may be or include trifluoromethane (CHF₃), carbon tetrafluoride (CF₄), or both. The one or more second etchant precursors may be or include diatomic chlorine (Cl₂), hydrogen bromide (HBr), sulfur hexafluoride (SF₆), or a combination thereof. The methods may include providing diatomic oxygen with the one or more first etchant precursors and/or the one or more second etchant precursors. The plasma effluents of the one or more first etchant precursors may be formed at a source power of greater than or about 2,000 W. The plasma effluents of the one or more second etchant precursors may be formed at a source power of less than or about 1,000 W. The methods may include applying a bias voltage while contacting the substrate with the plasma effluents of the one or more first etchant precursors and while contacting the substrate with the plasma effluents of the one or more second etchant precursors. The methods may include, subsequent to contacting the substrate with the plasma effluents of the one or more second etchant precursors to selectively etch polysilicon material, contacting the substate with a carbon-containing precursor.

Some embodiments of the present technology may encompass semiconductor processing methods. The methods may include providing one or more first etchant precursors to a processing region of a semiconductor processing chamber. A substrate may be housed within the processing region. A plurality of pairs of silicon oxide material and polysilicon material may be disposed on the substrate. The methods may include forming plasma effluents of the one or more first etchant precursors. The methods may include contacting the substrate with the plasma effluents of the one or more first etchant precursors to selectively etch silicon oxide material.

The methods may include providing one or more second etchant precursors to the processing region of the semiconductor processing chamber. The methods may include forming plasma effluents of the one or more second etchant precursors. The methods may include contacting the substrate with the plasma effluents of the one or more second etchant precursors to selectively etch polysilicon material. A temperature within the processing region may be less than or about −20° C.

In embodiments, a patterned mask material may be disposed on the alternating stack of silicon oxide material and polysilicon material. The patterned mask material may be or include a carbon-containing material. The one or more first etchant precursors may be or include hydrogen fluoride (HF), difluoromethane (CH₂F₂), or both. The one or more second etchant precursors may be or include sulfur hexafluoride (SF₆), carbon tetrafluoride (CF₄), or both. The plasma effluents of the one or more first etchant precursors may be formed at a source power of greater than or about 1,000 W. The plasma effluents of the one or more second etchant precursors may be formed at a source power of less than or about 1,500 W. The methods may include applying a bias power while contacting the substrate with the plasma effluents of the one or more first etchant precursors and while contacting the substrate with the plasma effluents of the one or more second etchant precursors. The methods may include, subsequent to contacting the substrate with the plasma effluents of the one or more first etchant precursors to selectively etch silicon oxide material, contacting the substate with a carbon-containing precursor. The methods may include, subsequent to contacting the substrate with the plasma effluents of the one or more first etchant precursors to selectively etch silicon oxide material, performing an oxygen soak to passivate the polysilicon material and/or purge to remove a residual amount of the one or more first etchant precursors and/or the one or more second etchant precursors.

Such technology may provide numerous benefits over conventional systems and techniques. For example, the processes may etch stacked pairs including alternating layers of silicon oxide material and polysilicon material within semiconductor structures. Additionally, the processes may etch uniformly etch through stacked pairs including with reduced clogging. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows a schematic cross-sectional view of an exemplary processing chamber according to some embodiments of the present technology.

FIG. 3 shows exemplary operations in a method according to some embodiments of the present technology.

FIGS. 4A-4D show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D DRAM to 3D DRAM, many process operations are modified from horizontal to vertical operations. Additionally, as 3D DRAM structures grow in the number of features being formed, the aspect ratios of structures increase, sometimes dramatically. During 3D DRAM processing, stacks of alternating layers of multiple dielectric materials may be disposed on a substrate. A variety of operations performed on these alternating layers before forming the 3D DRAM structure. For example, features, such as memory holes or trenches, may be etched into the alternating layers of multiple dielectric materials.

Many conventional technologies etching through alternating layers utilize an etch process that passivates sidewalls of the features. By passivating the sidewalls, a uniform profile of the features may be maintained, and lateral etching may be minimized. However, formation of the passivation material on the sidewalls, which may be a polymeric material, may not be uniform throughout a depth of the features, especially at increased depths. Accordingly, conventional technologies may suffer from pattern loading and/or bending.

The present technology overcomes these issues by performing an etch process using cyclic exposure first to one or more first etchant precursors and second to one or more second etchant precursors. The etchant precursors may be chosen to selectively etch the exposed material in the features, either silicon oxide material or polysilicon material. Additional purge operations or treatment operations may be performed to prevent clogging and/or maintain a mask material, respectively. The etch process may be performed at a reduced temperature, such as at a cryogenic temperature, that further maintains the mask material. Due to the high directionality of the etch, issues with memory hole or trench profile are reduced and/or eliminated.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

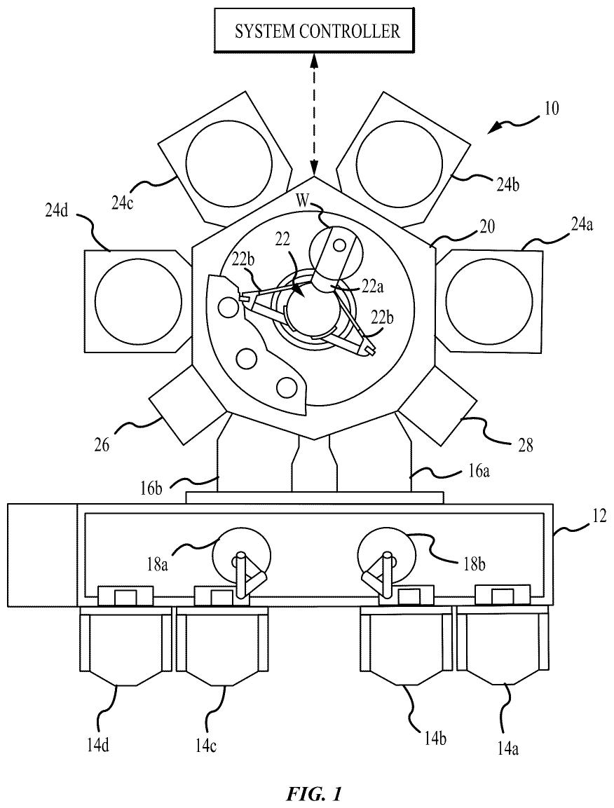

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions (CDs), sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

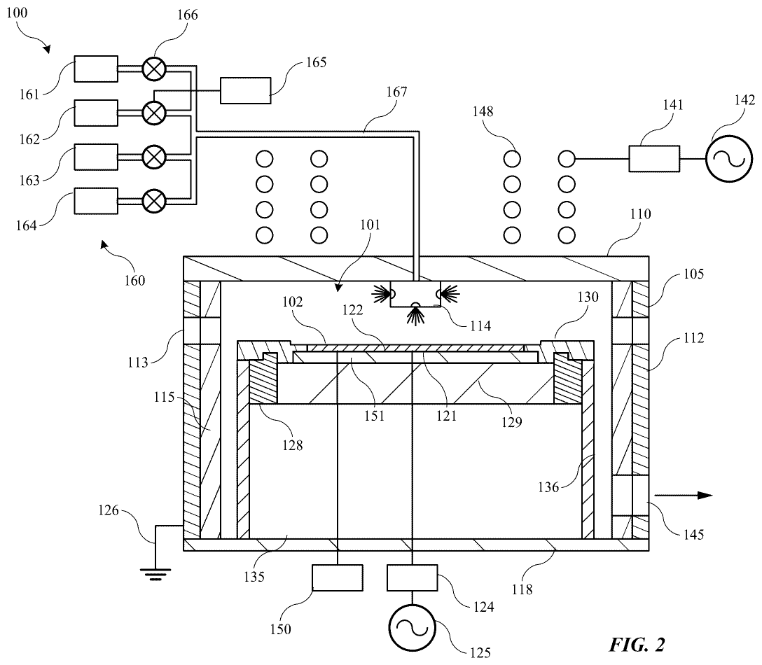

FIG. 2 illustrates a schematic cross-sectional view of an exemplary processing chamber 100 suitable for patterning a material layer disposed on a substrate 102 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 102 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 102 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as H₂, NH₃, H₂O, H₂O₂, NF₃, HF, F₂, Cl₂, CF₄, CHF₃, C₂F₆, C₂F₄, C₃F₆, C₄F₆, C₄F₈, BrF₃, ClF₃, SF₆, XeF₂, CH₃F, CH₂F₂, PF₃, BCl₃, SiCl₂, SiCl₄, ClF₃, H₂SiCl₂, PH₃, COS, and SO₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 102 and/or above the substrate 102 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 102 during processing. The substrate support pedestal 135 may include an electrostatic chuck (“ESC”) 122 for holding the substrate 102 during processing. The electrostatic chuck 122 may use the electrostatic attraction to hold the substrate 102 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 102 seated on the pedestal. The RF power supply 125 may cycle on and off, or pulse, during processing of the substrate 102. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 500 volts to about 15,000 volts to the electrode 121. The power source 150 may also include a system controller for controlling the operation of the electrode 121 by directing a DC current to the electrode 121 for chucking and de-chucking the substrate 102. For example, similar to the RF power supply 125, power supply 150 may provide a bias which attracts plasma ions, formed by the process gases in the chamber volume 101, to the ESC 122 and substrate 102 seated on the pedestal. The power supply 150 may cycle on and off, or pulse, during processing of the substrate 102. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 102 disposed thereon. The ESC 122 may be configured to perform in the temperature range required by the thermal budget of the device being fabricated on the substrate 102. For example, the ESC 122 may be configured to maintain the substrate 102 at a temperature of about −150° C. or lower to about 500° C. or higher depending on the process being performed.

The cooling base 129 may be provided to assist in controlling the temperature of the substrate 102. To mitigate process drift and time, the temperature of the substrate 102 may be maintained substantially constant by the cooling base 129 throughout the time the substrate 102 is in the cleaning chamber. In some embodiments, the temperature of the substrate 102 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 102, while shielding the top surface of the substrate support pedestal 135 from the plasma environment inside the plasma processing chamber 100. Lift pins may be selectively translated through the substrate support pedestal 135 to lift the substrate 102 above the substrate support pedestal 135 to facilitate access to the substrate 102 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

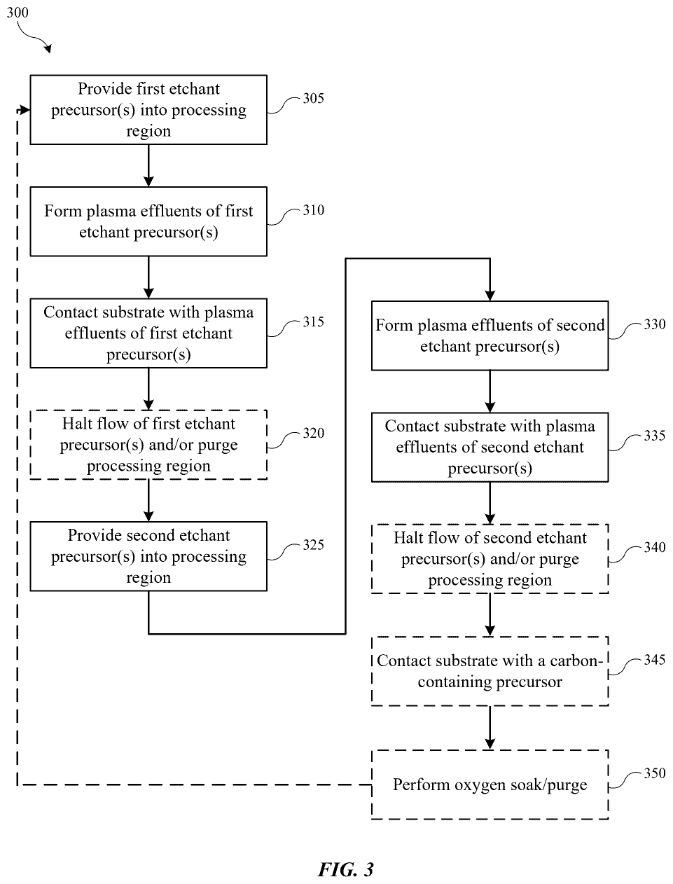

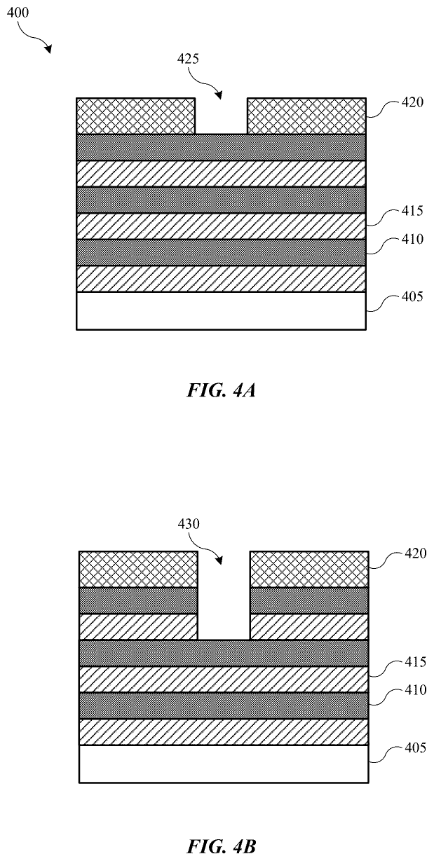

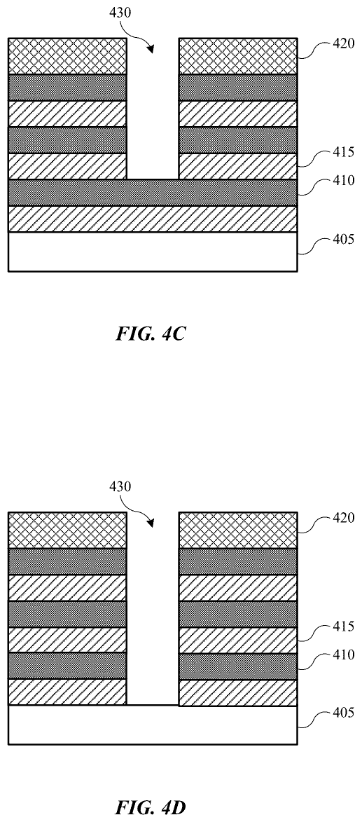

The chamber discussed previously may be used in performing exemplary methods, including etching methods, although any number of chambers may be configured to perform one or more aspects used in embodiments of the present technology. Turning to FIG. 3, exemplary operations in a method 300 according to embodiments of the present technology are shown. Method 300 may include one or more operations prior to the initiation of the method, including front end processing, deposition, etching, polishing, cleaning, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4D, the illustrations of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which etching of alternating layers of silicon oxide and polysilicon may be performed. As illustrated in FIG. 4A, substrate 405 may have a plurality of stacked layers overlying the substrate, which may be silicon, silicon germanium, or other substrate materials. The layers may include a first dielectric material 410, which may be silicon oxide, in alternating layers with second dielectric material 415, which may be polysilicon, for example. A plurality of pairs of the first dielectric material 410 and the second dielectric material 415 may be disposed on the substrate 405. Either the first dielectric material 410 or the second dielectric material 415 may be or include material that may be partially removed in subsequent operations. Although the remaining disclosure will discuss silicon oxide and polysilicon layers, any other known materials used in these two layers may be substituted for one or more of the layers. Although illustrated with only six layers of material, or three pairs of silicon oxide and polysilicon, exemplary structures may include any of the numbers of layers including hundreds of layers of material, and it is to be understood that the figures are only schematics to illustrate aspects of the present technology. For example, greater than or about 40 pairs of silicon oxide material and polysilicon material may be disposed on the substrate 405, such as greater than or about 45 pairs, greater than or about 50 pairs, greater than or about 55 pairs, greater than or about 60 pairs, greater than or about 65 pairs, greater than or about 70 pairs, greater than or about 75 pairs, greater than or about 80 pairs, or more.

Additionally, to allow for one or more memory holes or trenches to be formed through the alternating layers, a mask material 420 may be formed on the alternating layers of the first dielectric material 410 and the second dielectric material 415. The mask material 420 may be a carbon-containing material, such as a carbon hardmask, or any other mask material. The mask material 420 may be patterned to define one or more apertures 425, exposing a portion the underlying layer(s). Although only a single aperture 425 is illustrated, it is to be understood that exemplary structure 400 may include any number of apertures across the substrate 405 and mask material 420. Some or all of these operations may be performed in chambers or system tools as previously described, or may be performed in different chambers on the same system tool, which may include the chamber in which the operations of method 300 are performed.

Method 300 may be performed to etch or otherwise remove portions of the first dielectric material 510 and the second dielectric material 415, which may form memory holes or trenches in the structure 400 as illustrated. The method may be performed to facilitate control of the profile through the structure, and improve etch characteristics, such as uniformity of the memory holes or trenches as the etch progresses into the alternating layers. Method 300 may include iteratively etching the alternating layers of the first dielectric material 410 and the second dielectric material 415. Method 300 may include providing one or more first etchant precursors into a processing region housing the substrate 405 at operation 305. Method 300 may include forming plasma effluents of the one or more first etchant precursors at operation 310. At operation 315, method 300 may include contacting the substrate 405 with the plasma effluents of the one or more first etchant precursors to selectively etch the first dielectric material 410. After the first dielectric material 410 is etched to expose the underlying second dielectric material 415, method 300 may include halting a flow of the one or more first etchant precursors and/or purging the processing region at optional operation 320.

At operation 325, method 300 may include providing one or more second etchant precursors into the processing region at operation 325. Method 300 may include forming plasma effluents of the one or more second etchant precursors at operation 330. At operation 335, method 300 may include contacting the substrate 405 with the plasma effluents of the one or more second etchant precursors to selectively etch the second dielectric material 415. After the second dielectric material 415 is etched to expose the underlying first dielectric material 410, method 300 may include halting a flow of the one or more second etchant precursors and/or purging the processing region at optional operation 340. At optional operation 345, method 300 may include contacting the substrate 405 with plasma effluents of a carbon-containing precursor to rehabilitate the mask material 420, which may be damaged by the plasma effluents of the one or more first etchant precursors and/or plasma effluents of the one or more second etchant precursors. At optional operation 350, method 300 may include performing an oxygen soak and/or purge to remove residual etchant material and/or convert polysilicon material to silicon oxide material, which may prevent sidewall pitting. As illustrated in FIG. 4B, operations 305-350 may etch through a first pair of the first dielectric material 410 and the second dielectric material 415 to form a feature 430, such as a memory hole or trench, in the alternating layers. Again, although only a single feature 430 is illustrated, it is to be understood that exemplary structure 400 may include any number of memory holes or trenches across the substrate 405, which may align with apertures 425 in the mask material 420. As illustrated in FIGS. 4C-4D, the operations may be repeated for any number of cycles to iteratively etch the feature 430 into the alternating layers of the first dielectric material 410 and the second dielectric material 415. The number of cycles may be dependent on a desired depth of the feature 430. In embodiments, the depth of the feature 430 may extend through all of the alternating layers of the first dielectric material 410 and the second dielectric material 415, which may ultimately expose an upper surface of the substrate 405.

As previously discussed, method 300 may include providing one or more first etchant precursors to the processing region of the semiconductor processing chamber at operation 305. The one or more first etchant precursors may be selected to etch the first dielectric material 410, which may be exposed in the aperture 425 defined in the mask material 420. In embodiments, the exposed material, such as first dielectric material 410, may be silicon oxide. As such, the one or more first etchant precursors provided at operation 305 to etch the first dielectric material 410 may be or include a fluorine-containing precursor, such as carbon-and-fluorine-containing precursor. For example, the one or more first etchant precursors may be or include, but are not limited to, hydrogen fluoride (HF), trifluoromethane (CHF₃), carbon tetrafluoride (CF₄), difluoromethane (CH₂F₂), any other fluorine-containing precursor used or useful in semiconductor processing, or a combination thereof. The addition of CH₂F₂ may passivate sidewalls of the features 430 as they are being etched. The passivation may assist with maintaining CD while etching the features 430.

In embodiments, an oxygen-containing precursor may be provided with the one or more first etchant precursors. The oxygen-containing precursor may be or include, but is not limited to, diatomic oxygen (O₂), ozone (O₃), water or steam (H₂O), nitrous oxide (N₂O), nitrogen dioxide (NO₂), or any other oxygen-containing precursor used or useful in semiconductor processing. The one or more first etchant precursors may be provided with any number of additional precursors or carrier gases including nitrogen, argon, helium, or any number of additional materials, although in some embodiments the precursors may be limited to control side reactions or other aspects that may impact the fluorination and subsequent etching.

In embodiments, the one or more first etchant precursors may be or include HF and/or CH₂F₂ and may not include CHF₃ and/or CF₄. CHF₃ and CF₄, which may commonly be used to etch silicon oxide, may reduce the selectivity between the first dielectric material 410 and the mask material 420. For example, when the method 300 is performed at a cryogenic temperature, the one or more first etchant precursors may not include CHF₃ and/or CF₄ as selectivity between the first dielectric material 410 relative to the mask material 420 may decrease. As such, etching the first dielectric material 410 may be performed without CHF₃ and/or CF₄. Similarly, O₂ may consume the mask material 420, further reducing selectivity between the first dielectric material 410 and the mask material 420. As such, etching the first dielectric material 410 may be performed without O₂. Therefore, in embodiments, the processing region may be maintained free of Cl₂, HBr, and/or O₂ while etching the first dielectric material 410.

A total flow rate of the one or more first etchant precursors may be less than or about 750 sccm, and may be less than or about 700 sccm, less than or about 600 sccm, less than or about 500 sccm, less than or about 450 sccm, less than or about 400 sccm, less than or about 350 sccm, less than or about 300 sccm, less than or about 250 sccm, less than or about 200 sccm, less than or about 150 sccm, or less. A flow rate of the oxygen-containing precursor, if provided, may be less than or about 250 sccm, and may be less than or about 200 sccm, less than or about 150 sccm, less than or about 100 sccm, less than or about 75 sccm, less than or about 50 sccm, less than or about 40 sccm, less than or about 30 sccm, less than or about 20 sccm, or less.

At operation 310, method 300 may include forming plasma effluents of the one or more first etchant precursors and, if present, the oxygen-containing precursor and/or additional precursors or carrier gases. A source power used to form plasma effluents of the one or more first etchant precursors may be a relatively high plasma power. The relatively high plasma power may provide increased plasma density, which may increase etch rate and reduce etch delay. In embodiments, the plasma effluents of the one or more first etchant precursors may be formed at greater than or about 1,500 W, and may be formed at greater than or about 1,750 W, greater than or about 2,000 W, greater than or about 2,250 W, greater than or about 2,500 W, greater than or about 2,600 W, greater than or about 2,700 W, greater than or about 2,750 W, greater than or about 2,800 W, greater than or about 2,900 W, greater than or about 3,000 W, or more. However, very high plasma powers may result in reduced control of the etch and possible lateral etching. Therefore, the plasma effluents of the one or more first etchant precursors may be formed at less than or about 5,000 W, and may be formed at less than or about 4,500 W, less than or about 4,000 W, less than or about 3,500 W, less than or about 3,000 W, or less.

Method 300 may also include applying a bias voltage or a bias power. The bias voltage or the bias power may be applied to the substrate support pedestal. The bias voltage or the bias power may be applied while forming plasma effluents of the one or more first etchant precursors at operation 310 as well as while contacting the substrate 405 with the plasma effluents of the one or more first etchant precursors at operation 315. Applying the bias voltage or the bias power may increase directionality of the plasma effluents by drawing the plasma effluents to the substrate 405. As such, the bias voltage or the bias power may narrow the ion energy distribution function (IEDF) and/or the ion angular distribution function (IADF). The narrower IEDF may increase selectivity between the first dielectric material 410 and the mask material 420. The narrower IADF may reduce bowing of sidewalls defining the feature 430, such as by limiting lateral etching. In embodiments employing a bias voltage, the bias voltage may be between about 250 V and about 2,000 V. For example, the bias voltage may be less than or about 2,000 V, and may be less than or about 1,750 V, less than or about 1,500 V, less than or about 1,400 V, less than or about 1,300 V, less than or about 1,250 V, less than or about 1,200 V, less than or about 1,100 V, or less. Conversely, the bias voltage may be greater than or about 250 V, and may be greater than or about 500 V, greater than or about 600 V, greater than or about 700 V, greater than or about 800 V, greater than or about 900 V, greater than or about 1,000 V, greater than or about 1,100 V, or more. In embodiments employing a bias power, which may be a 2 MHz power, the bias power may be between about 250 W and about 2,000 W. For example, the bias power may be less than or about 2,000 W, and may be less than or about 1,750 W, less than or about 1,500 W, less than or about 1,250 W, less than or about 1,200 W, less than or about 1,100 W, or less. Conversely, the bias voltage may be greater than or about 250 W, and may be greater than or about 500 W, greater than or about 600 W, greater than or about 700 W, greater than or about 800 W, greater than or about 900 W, greater than or about 1,000 W, greater than or about 1,100 W, or more.

In embodiments, the bias voltage or the bias power may not be applied continuously. While constant application, or continuous wave, of the bias voltage or the bias power is contemplated, pulsing the bias voltage or the bias power may reduce the effective bias voltage or bias power. Constant application, or continuous wave, of the bias voltage or the bias power may damage the structure, whereas pulsing the bias voltage or the bias power may limit damage to the structure while maintaining desired directionality, ion energy, and/or ion angle of the plasma effluents. In embodiments, a power on time (POT) of the bias voltage or a duty cycle (DC) of the bias power may be between about 1% and about 50%. For example, the POT of the bias voltage or the DC of the bias power may be less than or about 50%, and may be less than or about 45%, less than or about 40%, less than or about 35%, less than or about 30%, less than or about 25%, less than or about 20%, less than or about 15%, less than or about 10%, less than or about 5%, or less. Conversely, the POT of the bias voltage or the DC of the bias power may be greater than or about 1%, and may be greater than or about 2%, greater than or about 4%, greater than or about 5%, greater than or about 6%, greater than or about 8%, greater than or about 10%, greater than or about 12%, greater than or about 14%, greater than or about 15%, greater than or about 20%, greater than or about 30%, greater than or about 40%, greater than or about 50%, or more.

At operation 315, method 300 may include contacting the substrate 405, including the first dielectric material 410, with the plasma effluents of the one or more first etchant precursors. The contacting may selectively etch the first dielectric material 410, such silicon oxide material, relative to the second dielectric material 415, such as polysilicon material. The contacting may continue for a first period of time sufficient to etch a thickness of the first dielectric material 410. The first period of time, which may be selected based on the thickness of the first dielectric material 410, may be between about 0.5 seconds and about 20 seconds. For example, the first period of time may be less than or about 20 seconds, and may be less than or about 18 seconds, less than or about 16 seconds, less than or about 14 seconds, less than or about 12 seconds, less than or about 10 seconds, less than or about 9 seconds, less than or about 8 seconds, less than or about 7 seconds, less than or about 6 seconds, less than or about 5 seconds, or less. Alternatively, the first period of time may be greater than or about 0.5 seconds, and may be greater than or about 1 second, greater than or about 2 seconds, greater than or about 3 seconds, greater than or about 4 seconds, greater than or about 5 seconds, greater than or about 6 seconds, greater than or about 7 seconds, greater than or about 8 seconds, greater than or about 9 seconds, greater than or about 10 seconds, or more.

At optional operation 320, method 300 may include halting a flow of any of the precursors or gases being provided. For example, a flow rate of any of the one or more first etchant precursors, the oxygen-containing precursor, and/or any additional precursors or inert gases may be halted. Additionally, method 300 may include purging the processing region at optional operation 320. Puring the processing region may include providing an inert gas (or maintaining a flow of inert gas already being provided), such as any of the previously discussed inert gases, to remove any residual precursors or byproducts. For example, purging the processing region at optional operation 320 may include providing argon at a flow rate of between about 250 sccm and about 1,000 sccm for between about 1 second and about 30 seconds. While purging the processing region, the source power may be reduced to limit bombardment. For example, the source power may be reduced to less than or about 250 W, such as less than or about 200 W, less than or about 150 W, or less. Additionally, pressure may be maintained relatively low to allow removal of precursors or byproducts within the feature 430. Pressure within the processing region may be less than or about 50 mTorr, such as less than or about 20 mTorr, less than or about 10 mTorr, or less.

Method 300 may include providing one or more second etchant precursors to the processing region of the semiconductor processing chamber at operation 325. The one or more second etchant precursors may be selected to etch the second dielectric material 415, which may be exposed in the aperture 425 defined in the mask material 420. In embodiments, the exposed material, such as second dielectric material 415, may be polysilicon. As such, the one or more second etchant precursors provided at operation 325 to etch the second dielectric material 415 may be or include a halogen-containing precursor, such as a fluorine-containing precursor, a bromine-containing precursor, or a chlorine-containing precursor. For example, the one or more second etchant precursors may be or include, but are not limited to, diatomic chlorine (Cl₂), hydrogen bromide (HBr), sulfur hexafluoride (SF₆), carbon tetrafluoride (CF₄), any other halogen-containing precursor used or useful in semiconductor processing, or a combination thereof.

In embodiments, an oxygen-containing precursor may be provided with the one or more second etchant precursors. The oxygen-containing precursor may be or include any of the previously discussed oxygen-containing precursors. The one or more second etchant precursors may be provided with any number of additional precursors or carrier gases including nitrogen, argon, helium, or any number of additional materials, although in some embodiments the precursors may be limited to control side reactions or other aspects that may impact the halogenation and subsequent etching.

In embodiments, the one or more second etchant precursors may be or include SF₆ and/or CF₄ and may not include Cl₂ and/or HBr. Cl₂ and HBr, which may commonly be used to etch polysilicon material, may reduce the selectivity between the second dielectric material 415 and the mask material 420. For example, when the method 300 is performed at a cryogenic temperature, the one or more second etchant precursors may not include Cl₂ and/or HBr as selectivity between the second dielectric material 415 relative to the mask material 420 may decrease. As such, etching the second dielectric material 415 may be performed without Cl₂ and/or HBr. Similarly, O₂ may consume the mask material 420, further reducing selectivity between the second dielectric material 415 and the mask material 420. As such, etching the second dielectric material 415 may be performed without O₂. Therefore, in embodiments, the processing region may be maintained free of Cl₂, HBr, and/or O₂ while etching the second dielectric material 415.

A total flow rate of the one or more second etchant precursors may be less than or about 750 sccm, and may be less than or about 700 sccm, less than or about 600 sccm, less than or about 500 sccm, less than or about 450 sccm, less than or about 400 sccm, less than or about 350 sccm, less than or about 300 sccm, less than or about 250 sccm, less than or about 200 sccm, less than or about 150 sccm, or less. A flow rate of the oxygen-containing precursor, if provided, may be less than or about 250 sccm, and may be less than or about 200 sccm, less than or about 150 sccm, less than or about 100 sccm, less than or about 75 sccm, less than or about 50 sccm, less than or about 40 sccm, less than or about 30 sccm, less than or about 20 sccm, or less.

At operation 330, method 300 may include forming plasma effluents of the one or more second etchant precursors and, if present, the oxygen-containing precursor and/or additional precursors or carrier gases. The source power used to form plasma effluents of the one or more second etchant precursors may be a relatively low plasma power, especially compared to the source power used to form plasma effluents of the one or more first etchant precursors. The relatively low source power may increase control of the plasma density, which may better control the etch rate of the second dielectric material 415. In embodiments, the plasma effluents of the one or more second etchant precursors may be formed at less than or about 1,500 W, and may be formed at greater than or about 1,250 W, less than or about 1,000 W, less than or about 950 W, less than or about 900 W, less than or about 850 W, less than or about 800 W, less than or about 750 W, less than or about 700 W, less than or about 650 W, less than or about 600 W, or less. However, very low source powers may result reduced plasma density and reduced etch rate. Therefore, the plasma effluents of the one or more second etchant precursors may be formed at greater than or about 250 W, and may be formed at greater than or about 300 W, greater than or about 400 W, greater than or about 500 W, greater than or about 600 W, or more.

In embodiments, the source power may be pulsed at operation 330. While constant application, or continuous wave, of source power is contemplated, pulsing the source power may reduce the effective source power. For example, the DC of the source power at operation 330 may be between about 1% and about 50%. The DC of the source power may be less than or about 50%, and may be less than or about 45%, less than or about 40%, less than or about 35%, less than or about 30%, less than or about 25%, less than or about 20%, less than or about 18%, less than or about 16%, less than or about 14%, less than or about 12%, less than or about 10%, less than or about 5%, or less. Conversely, the DC of the source power may be greater than or about 5%, and may be greater than or about 6%, greater than or about 8%, greater than or about 10%, greater than or about 12%, greater than or about 14%, greater than or about 15%, greater than or about 20%, greater than or about 30%, greater than or about 40%, greater than or about 50%, or more.

Method 300 may also include applying the bias voltage or the bias power while forming plasma effluents of the one or more second etchant precursors at operation 330 as well as while contacting the substrate 405 with the plasma effluents of the one or more second etchant precursors at operation 335. As previously discussed, applying the bias voltage or the bias power may increase directionality of the plasma effluents by drawing the plasma effluents to the substrate 405. The bias voltage while etching the second dielectric material 415, which may be polysilicon material, may be less than or about 2,000 V, and may be less than or about 1,750 V, less than or about 1,500 V, less than or about 1,400 V, less than or about 1,300 V, less than or about 1,250 V, less than or about 1,200 V, less than or about 1,100 V, or less. Conversely, the bias voltage may be greater than or about 250 V, and may be greater than or about 500 V, greater than or about 600 V, greater than or about 700 V, greater than or about 800 V, greater than or about 900 V, greater than or about 1,000 V, greater than or about 1,100 V, or more. In embodiments employing a bias power, which again may be a 2 MHz power, the bias power may be between about 250 W and about 2,000 W. For example, the bias power may be less than or about 2,000 W, and may be less than or about 1,750 W, less than or about 1,500 W, less than or about 1,250 W, less than or about 1,200 W, less than or about 1,100 W, less than or about 1,000 W, less than or about 900 W, or less. Conversely, the bias voltage may be greater than or about 250 W, and may be greater than or about 500 W, greater than or about 600 W, greater than or about 700 W, greater than or about 800 W, greater than or about 900 W, or more.

Similar to the bias voltage and the bias power previously discussed, POT of the bias voltage or DC of the bias power may be between about 1% and about 50%. For example, the POT of the bias voltage or the DC of the bias power may be less than or about 50%, and may be less than or about 45%, less than or about 40%, less than or about 35%, less than or about 30%, less than or about 25%, less than or about 20%, less than or about 15%, less than or about 10%, less than or about 5%, or less. Conversely, the POT of the bias voltage or the DC of the bias power may be greater than or about 1%, and may be greater than or about 2%, greater than or about 4%, greater than or about 5%, greater than or about 6%, greater than or about 8%, greater than or about 10%, greater than or about 12%, greater than or about 14%, greater than or about 15%, greater than or about 20%, greater than or about 30%, greater than or about 40%, greater than or about 50%, or more.

At operation 335, method 300 may include contacting the substrate 405, including the second dielectric material 415, with the plasma effluents of the one or more second etchant precursors. The contacting may selectively etch the second dielectric material 415, such polysilicon material, relative to the first dielectric material 410, such as silicon oxide material. The contacting may continue for a second period of time sufficient to etch a thickness of the second dielectric material 415. The second period of time, which may be selected based on the thickness of the second dielectric material 415, may be between about 10 seconds and about 60 seconds. For example, the second period of time may be less than or about 60 seconds, and may be less than or about 55 seconds, less than or about 50 seconds, less than or about 45 seconds, less than or about 40 seconds, less than or about 35 seconds, less than or about 30 seconds, less than or about 25 seconds, less than or about 20 seconds, less than or about 15 seconds, less than or about 10 seconds, or less. Alternatively, the second period of time may be greater than or about 10 seconds, and may be greater than or about 15 second, greater than or about 20 seconds, greater than or about 25 seconds, greater than or about 30 seconds, greater than or about 35 seconds, greater than or about 40 seconds, greater than or about 45 seconds, greater than or about 50 seconds, greater than or about 55 seconds, greater than or about 60 seconds, or more. In embodiments, the second period of time may be increased as the etch progresses into the alternating layers of the first dielectric material 410 and the second dielectric material 415. The increase in the second period of time may ensure the feature 430 etches through the entire thickness of the second dielectric material 415. In embodiments, the second period of time may increase between about 0.1 seconds and about 1 second per tier.

At optional operation 340, method 300 may include halting a flow of any of the precursors or gases being provided. For example, a flow rate of any of the one or more second etchant precursors, the oxygen-containing precursor, and/or any additional precursors or inert gases may be halted. Additionally, method 300 may include purging the processing region at optional operation 340. Puring the processing region at optional operation 340 may include any of the features as previously discussed with regard to the purge at optional operation 320.

In embodiments, method 300 may include contacting the substrate 405 with a carbon-containing precursor or plasma effluents thereof at optional operation 345. As the halogen-containing precursors of the one or more first etchant precursors and/or the second one or more second etchant precursors may consume the mask material 420, contacting the substrate 405 with the carbon-containing precursor or plasma effluents thereof may re-deposit carbon-containing material or re-introduce depleted carbon to the mask material 420, which may be a carbon-containing material as previously discussed. This re-deposition of carbon-containing material or re-introduction of depleted carbon may repair the mask material 420, which may selectivity between the etching of the first dielectric material 410 and/or the second dielectric material 415 relative to the mask material 420. Sidewalls of the features 430 may be characterized by increased smoothness/reduced roughness due to efficient polymer formation/protection, which may form during optional operation 345. In embodiments, the polymer may more readily form at reduced temperatures, such as cryogenic temperatures. However, the polymer may also form at non-cryogenic temperatures although formation may be at a reduced rate.

Optional operation 345 may include providing a carbon-containing precursor to the processing region, optionally forming plasma effluents of the carbon-containing precursor, and contacting the substrate 405, including mask material 420, with the carbon-containing precursor or plasma effluents thereof. For example, contacting the substrate 405 with the carbon-containing precursor or plasma effluents thereof at optional operation 345 may include providing the carbon-containing precursor, which may be any of the previously mentioned precursors including carbon, at a flow rate of between about 25 sccm and about 250 sccm for between about 1 second and about 30 seconds. While providing the carbon-containing precursor to the processing region, the source power may be between about 1,000 W and about 5,000 W. During optional operation 345, bias voltage or bias power may be limited or zero. Additionally, pressure may be maintained at less than or about 50 mTorr, such as less than or about 20 mTorr, less than or about 10 mTorr, or less.

At optional operation 350, method 300 may include performing an oxygen soak and/or purge. As the etch proceeds through stacked pairs of the first dielectric material 410 and the second dielectric material 415, sidewall passivation may become less prevalent/efficient. For example, embodiments using lean chemistry without O₂ may result in less passivation of the second dielectric material 415, which may be polysilicon. In embodiments using O₂ during processing, the second dielectric material 415, which may be polysilicon, may be partially oxidized to form silicon oxide, which may be more resilient to etching. Additionally, as the etch proceeds through stacked pairs of the first dielectric material 410 and the second dielectric material 415, polymer formation at optional operation 345 may not fully reach lower portions of the feature 430. As such, layers of the second dielectric material 415 towards the etch front or bottom of the feature 430 may not be adequately protected by oxidation and/or polymer formation. With continued exposure to etchant precursors, as the etch continues and deepens, the second dielectric material 415 may be prone to being etched or damaged, such as through pitting. As such, the present technology may perform an intermittent, such as after a plurality of cycles, oxygen soak and/or purge to prevent pitting of the second dielectric material 415.

Optional operation 350 may include providing an oxygen-containing precursor to the processing region. The oxygen-containing precursor may be or include O₂, O₃, H₂O, N₂O, NO₂, or any other oxygen-containing precursor used or useful in semiconductor processing. A flow rate of the oxygen-containing precursor may be sufficient to oxidize some layers of the second dielectric material 415. For example, the flow rate of the oxygen-containing precursor may be greater than or about 100 sccm, and may be greater than or about 150 sccm, greater than or about 200 sccm, greater than or about 250 sccm, greater than or about 300 sccm, greater than or about 350 sccm, greater than or about 400 sccm, greater than or about 450 sccm, greater than or about 500 sccm, or more.

At optional operation 350, plasma effluents of the oxygen-containing precursor may be formed. While a thermal operation (e.g., plasma-free or no plasma power applied) may benefit maintaining the mask material 420, halting the plasma may reduce productivity (i.e., throughput). Therefore, the plasma power may be reduced at optional operation 350 relative to operation(s) preceding the oxygen soak. In embodiments, the plasma effluents of the oxygen-containing may be formed at less than or about 500 W, and may be formed at less than or about 450 W, less than or about 400 W, less than or about 350 W, less than or about 300 W, less than or about 250 W, less than or about 200 W, less than or about 150 W, less than or about 100 W, less than or about 50 W, or less. Optional operation 350 may be performed without the application of bias power or bias voltage.

The oxygen soak may proceed for a duration of time to ensure adequate passivation of sidewalls the second dielectric material 415. In embodiments, the oxygen soak may proceed for greater than or about 10 seconds, and may proceed for greater than or about 20 seconds, greater than or about 30 seconds, greater than or about 40 seconds, greater than or about 50 seconds, greater than or about 60 seconds, greater than or about 70 seconds, greater than or about 80 seconds, greater than or about 90 seconds, greater than or about 100 seconds, greater than or about 110 seconds, greater than or about 120 seconds, or more.

Subsequent to the oxygen soak, the processing region may be purged. Purging the processing region may remove any residual etchant material, such as a residual portion of the one or more first etchant precursors and/or the one or more second etchant precursors, which may include fluorine constituents, which may be present in the features 430. If left in the features 430, the residual etchant material, such as any fluorine constituents, may begin to uncontrollably etch the first dielectric material 410, the second dielectric material 415, and/or the silicon oxide passivation formed on the second dielectric material 415 as the method 300 switches between various operations, such as, for example, between optional operation 345 and operation 305 or between optional operation 320 and operation 325. As such, optional operation 350 may also include purging the processing region. The purge may include providing an inert precursor, such as nitrogen, argon, or helium, to the processing region and flushing the processing region.

Similar to the oxygen soak, plasma power may be minimized during the purge to reduce/prevent plasma formation of the inert precursor, which may result in sputtering of materials on the substrate 405. A duration of the purge may be sufficient to remove residual etchant material from the processing region. For example, the duration of the purge may be greater than or about 10 seconds, and may be greater than or about 15 seconds, greater than or about 20 seconds, greater than or about 25 seconds, greater than or about 30 seconds, greater than or about 35 seconds, greater than or about 40 seconds, greater than or about 45 seconds, greater than or about 50 seconds, greater than or about 55 seconds, greater than or about 60 seconds, or more.

While discussed as being performed after rehabilitating the mask material at optional operation 345, optional operation 350 may be performed at any sequence in method 300. Optional operation 350 may be performed at any time prior to potential pitting of the second dielectric material 415.

As illustrated in FIGS. 4C-4D, to further facilitate directional etching, the present technology may be performed in a number of cycles to allow removal of the alternating layers of the first dielectric material 410 and the second dielectric material 415. In some embodiments, method 300 may include repeating the operations 305-350 for any number of cycles, such as greater than 20 cycles, greater than 30 cycles, greater than 40 cycles, greater than 50 cycles, greater than 60 cycles, greater than 70 cycles, greater than 80 cycles, or more. It is contemplated that the operations 305-350 of method 300 may be repeated any number of times depending on depth of the feature 430 to be etched or the number of pairs of the first dielectric material 410 and the second dielectric material 415 to be etched. In embodiments, an aspect ratio, or ratio of length/height to width of the resultant feature 430, may be greater than or about 10:1, and may be greater than or about 15:1, greater than or about 20:1, greater than or about 25:1, greater than or about 30:1, greater than or about 35:1, greater than or about 40:1, greater than or about 45:1, greater than or about 50:1, or more. Individual cycles when repeating operations 305-350 of method 300 may include various operations. For example, contacting the substrate 405 with plasma effluents of the carbon-containing precursor to rehabilitate the mask material 420 at optional operation 345 may be performed intermittently or after a number of cycles. Similarly, performing the oxygen soak and/or purge to remove residual etchant material and/or convert polysilicon material to silicon oxide material at optional operation 350 may be performed intermittently or after a number of cycles.

Process conditions may also impact the operations performed in method 300. Each of the operations of method 300 may be performed during a constant temperature in embodiments, while in some embodiments the temperature may be adjusted during different operations. Temperatures may be maintained in any range, however, at higher temperatures, etch rates of the first dielectric material 410 and/or the second dielectric material 415 may increase. Additionally, higher temperatures may result in faster consumption of the mask material 420. As such, in embodiments, any or all operations of the method 300 may performed at a temperature of less than or about 100° C., and may be performed at a temperature of less than or about 80° C., less than or about 75° C., less than or about 60° C., less than or about 50° C., less than or about 40° C., less than or about 25° C., less than or about 20° C., less than or about 0° C., less than or about −10° C., less than or about −20° C., less than or about −30° C., less than or about −40° C., less than or about −50° C., less than or about −60° C., less than or about −70° C., less than or about −80° C., less than or about −90° C., or less. While reduced temperatures may limit consumption of the mask material 420, etch rates of the first dielectric material 410 and/or the second dielectric material 415 may reduce, thereby increasing processing times. As such, any or all operations of the method 300 may performed at a temperature of greater than or about −90° C., and may be performed at a temperature of greater than or about −80° C., greater than or about −70° C., greater than or about −60° C., greater than or about −50° C., greater than or about −40° C., greater than or about −30° C., greater than or about −20° C., greater than or about −10° C., greater than or about 0° C., greater than or about 20° C., greater than or about 25° C., greater than or about 40° C., greater than or about 50° C., greater than or about 60° C., greater than or about 75° C., greater than or about 80° C., or more.

Each of the operations of method 300 may be performed during a constant pressure in embodiments, while in some embodiments the pressure may be adjusted during different operations. Pressures may be maintained in any range, however, at higher pressures, further dissociation of the etchant precursors may occur, which may produce more etchant radicals. As the amount of etchant radicals increases, directionality of the etch may decrease and the profile of the feature 430 may suffer. Accordingly, in some embodiments, any or all operations of the method 300 may performed at a pressure of less than or about 100 mTorr, and may be performed at a pressure of less than or about 90 mTorr, less than or about 80 mTorr, less than or about 75 mTorr, less than or about 70 mTorr, less than or about 60 mTorr, less than or about 50 mTorr, less than or about 45 mTorr, less than or about 40 mTorr, less than or about 35 mTorr, less than or about 30 mTorr, less than or about 25 mTorr, less than or about 20 mTorr, less than or about 15 mTorr, less than or about 10 mTorr, less than or about 5 mTorr, or less. However, while directionality of the etch may increase at lower pressures, lower pressures may also result in decreased etch rate. As such, in some embodiments, any or all operations of the method 300 may performed at a pressure of greater than or about 5 mTorr, and may be performed at a pressure of greater than or about 10 mTorr, greater than or about 15 mTorr, greater than or about 20 mTorr, greater than or about 25 mTorr, greater than or about 30 mTorr, greater than or about 35 mTorr, greater than or about 40 mTorr, greater than or about 45 mTorr, greater than or about 50 mTorr, greater than or about 55 mTorr, greater than or about 60 mTorr, greater than or about 65 mTorr, greater than or about 70 mTorr, greater than or about 75 mTorr, greater than or about 80 mTorr, greater than or about 90 mTorr, greater than or about 100 mTorr, or more.

In embodiments, the pressure may be adjusted between operations. For example, operations 305-315 to selectively etch the first dielectric material 410, such as silicon oxide material, may be performed at a first pressure. The first pressure may be between about 1 mTorr and about 25 mTorr. Subsequent to selectively etching the first dielectric material 410, operations 325-335 to selectively etch the second dielectric material 415, such as polysilicon material, may be performed at a second pressure greater than the first pressure. The second pressure may be, for example, between about 25 mTorr and about 40 mTorr. Finally, optional operation 345, whether performed after selectively etching the first dielectric material 410 or the second dielectric material 415 may be performed at a third pressure. The third pressure may be, for example, between about 25 mTorr and about 35 mTorr. As such, pressure may be adjusted numerous times during method 300.

The present technology may permit a highly selective etch of the first dielectric material 410, such as silicon oxide material, the second dielectric material 415, such as polysilicon material. Additionally, by adjusting one or more process conditions and/or chemistry being provided to the processing region, a highly selective etch of the second dielectric material 415, such as polysilicon material, relative to the first dielectric material 410, such as silicon oxide material, may be performed. Due to the highly selective etching of the first dielectric material 410 and/or the second dielectric material 415, the etch may be able to precisely stop on a desired tier within the stacked pairs of the first dielectric material 410 and the second dielectric material 415. For example, the etch may be controlled to stop at any desired tier target (i.e., the fifth tier, the tenth tier, the twentieth tier, the thirtieth tier, the fortieth tier, the fiftieth tier, the sixtieth tier, the seventieth tier, the eightieth tier, and beyond).

The one or more process conditions and/or chemistry may provide increased selectivity of the material to be etched, the first dielectric material 410 or the second dielectric material 415, relative to the mask material 420, such as carbon-containing material. For example, at reduced temperatures, such as cryogenic temperatures, selectivity between the material to be etched, the first dielectric material 410 or the second dielectric material 415, relative to the mask material 420, such as carbon-containing material, may be increased. The increased selectivity may provide higher mask material 420 selectivity and reduce damage, such as faceting, to the mask material 420. The increased selectivity may maintain the mask material 420, thereby permitting deeper etches to further stacked pairs of the first dielectric material 410 and the second dielectric material 415. Additionally, in embodiments being performed at reduced temperatures, such as cryogenic temperatures, an etch rate of the first dielectric material 410, such as silicon oxide material, may be increased, thereby contributing to improved throughput.

In embodiments being performed at increased temperatures, such as non-cryogenic temperatures, an etch rate of the second dielectric material 415, such as polysilicon material, may be increased, thereby contributing to improved throughput. In embodiments, the process may utilize both a cryogenic temperature and a non-cryogenic temperature. For example, initial etching may benefit from a non-cryogenic temperature, which may increase etch rate of the second dielectric material 415. As the etch proceeds, increased selectivity relative to the mask material 420 may be necessary to maintain the mask material 420. As such, the temperature may be reduced, such as to a cryogenic temperature. A chiller may be used to reduce the temperature within the processing region.

Whether performed at a cryogenic temperature or non-cryogenic temperature, the present technology may benefit from increased etch uniformity across the substrate 405. For example, the etch may be substantially uniform from the center of the substrate 405 to the middle of the substrate 405 and to the edge of the substrate 405. In addition to uniformity in the lateral direction across the substrate 405, the features being etched through the stacked pairs of the first dielectric material 410 and the second dielectric material 415 may be characterized by a highly uniform CD. For example, the top CD and bottom CD may be substantially equal with minimal bowing CD along a length of the feature being etched. With a highly uniform CD, sidewalls of the feature being etched may be characterized by increased smoothness.

Furthermore, the present technology may be extended to other applications, such as a binary mask etch scheme.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing one or more first etchant precursors to a processing region of a semiconductor processing chamber, wherein a substrate is housed within the processing region, and wherein a plurality of pairs of silicon oxide material and polysilicon material are disposed on the substrate;
forming plasma effluents of the one or more first etchant precursors;
contacting the substrate with the plasma effluents of the one or more first etchant precursors to selectively etch silicon oxide material;
providing one or more second etchant precursors to the processing region of the semiconductor processing chamber;
forming plasma effluents of the one or more second etchant precursors; and
contacting the substrate with the plasma effluents of the one or more second etchant precursors to selectively etch polysilicon material, wherein a temperature within the processing region is greater than or about 0° C.

2. The semiconductor processing method of claim 1, wherein a patterned mask material is disposed on the alternating stack of silicon oxide material and polysilicon material.

3. The semiconductor processing method of claim 2, wherein the patterned mask material comprises a carbon-containing material.

4. The semiconductor processing method of claim 1, wherein the one or more first etchant precursors comprise trifluoromethane (CHF₃), carbon tetrafluoride (CF₄), or both.

5. The semiconductor processing method of claim 1, wherein the one or more second etchant precursors comprise diatomic chlorine (Cl₂), hydrogen bromide (HBr), sulfur hexafluoride (SF₆), or a combination thereof.

6. The semiconductor processing method of claim 1, further comprising:
providing diatomic oxygen with the one or more first etchant precursors and/or the one or more second etchant precursors.

7. The semiconductor processing method of claim 1, wherein the plasma effluents of the one or more first etchant precursors are formed at a source power of greater than or about 2,000 W.

8. The semiconductor processing method of claim 1, wherein the plasma effluents of the one or more second etchant precursors are formed at a source power of less than or about 1,000 W.

9. The semiconductor processing method of claim 1, further comprising:
applying a bias voltage while contacting the substrate with the plasma effluents of the one or more first etchant precursors and while contacting the substrate with the plasma effluents of the one or more second etchant precursors.

10. The semiconductor processing method of claim 1, further comprising:
subsequent to contacting the substrate with the plasma effluents of the one or more second etchant precursors to selectively etch polysilicon material, contacting the substate with a carbon-containing precursor.

11. A semiconductor processing method comprising:
providing one or more first etchant precursors to a processing region of a semiconductor processing chamber, wherein a substrate is housed within the processing region, and wherein a plurality of pairs of silicon oxide material and polysilicon material are disposed on the substrate;
forming plasma effluents of the one or more first etchant precursors;
contacting the substrate with the plasma effluents of the one or more first etchant precursors to selectively etch silicon oxide material;
providing one or more second etchant precursors to the processing region of the semiconductor processing chamber;
forming plasma effluents of the one or more second etchant precursors; and
contacting the substrate with the plasma effluents of the one or more second etchant precursors to selectively etch polysilicon material, wherein a temperature within the processing region is less than or about −20° C.

12. The semiconductor processing method of claim 11, wherein a patterned mask material is disposed on the alternating stack of silicon oxide material and polysilicon material.

13. The semiconductor processing method of claim 12, wherein the patterned mask material comprises a carbon-containing material.

14. The semiconductor processing method of claim 11, wherein the one or more first etchant precursors comprise hydrogen fluoride (HF), difluoromethane (CH₂F₂), or both.

15. The semiconductor processing method of claim 11, wherein the one or more second etchant precursors comprise sulfur hexafluoride (SF₆), carbon tetrafluoride (CF₄), or both.

16. The semiconductor processing method of claim 11, wherein the plasma effluents of the one or more first etchant precursors are formed at a source power of greater than or about 1,000 W.

17. The semiconductor processing method of claim 11, wherein the plasma effluents of the one or more second etchant precursors are formed at a source power of less than or about 1,500 W.

18. The semiconductor processing method of claim 11, further comprising:
applying a bias power while contacting the substrate with the plasma effluents of the one or more first etchant precursors and while contacting the substrate with the plasma effluents of the one or more second etchant precursors.

19. The semiconductor processing method of claim 11, further comprising:
subsequent to contacting the substrate with the plasma effluents of the one or more first etchant precursors to selectively etch silicon oxide material, contacting the substate with a carbon-containing precursor.

20. The semiconductor processing method of claim 11, further comprising:
subsequent to contacting the substrate with the plasma effluents of the one or more first etchant precursors to selectively etch silicon oxide material, performing an oxygen soak to passivate the polysilicon material and/or purge to remove a residual amount of the one or more first etchant precursors and/or the one or more second etchant precursors.
